(19) United States
(12) Patent Application Publication
(10) Pub. No.: US 2016/0088770 A1
(43) Pub. Date: Mar. 24, 2016

(54) HEATSINK EQUIPPED WITH PLURAL FINS WHOSE CONNECTION METHODS ARE DIFFERENT

(71) Applicant: FANUC CORPORATION, Yamanashi (JP)

(72) Inventor: Kenichi Okuaki, Yamanashi (JP)

(21) Appl. No.: 14/857,902

(22) Filed: Sep. 18, 2015

(30) Foreign Application Priority Data
Sep. 22, 2014 (JP) 2014-193004

(51) Int. Cl. H05K 7/20

(52) U.S. Cl. CPC H05K 7/20418

(57) ABSTRACT

A heatsink comprises a heat receiving member having a first surface to which a heat generating component which needs to be cooled is attached and a second surface which is opposite to the first surface, and a plurality of fins protrudingly provided from the second surface of the heat receiving member. The plurality of fins include a first fin protrudingly provided on a first region of the second surface of the heat receiving member by a first attachment structure, and a second fin protrudingly provided on a second region of the second surface of the heat receiving member by a second attachment structure different from the first attachment structure.

### BACKGROUND OF THE INVENTION

1. Field of the Invention

The present invention relates to a heatsink for cooling a heat generating component.

2. Description of the Related Art

Conventionally, a heatsink (radiator) in which separate heat generating components are attached to flat surfaces different from each other is known (for example, refer to Japanese Laid-open Patent Publication No. 2010-187504). In the heatsink described in Japanese Laid-open Patent Publication No. 2010-187504, a module including a semiconductor switching element and a smoothing capacitor are attached to the flat surfaces different from each other of the heatsink. In addition, a fin for the module is provided at a place corresponding to the flat surface to which the module is attached. A fin for the smoothing capacitor is provided at a place corresponding to the flat surface to which the smoothing capacitor is attached.

In the above-described heatsink described in Japanese Laid-open Patent Publication No. 2010-187504, the fin for the module, which corresponds to the module, and the fin for the smoothing capacitor, which corresponds to the smoothing capacitor, are provided by the same attachment structure as each other. Thus, for example, when the calorific value of the module and the calorific value of the smoothing capacitor are different from each other, it is difficult for the heatsink to provide optimum radiation performance based on the respective calorific values.

### SUMMARY OF INVENTION

One mode of the present invention is a heatsink including a heat receiving member having a first surface to which a heat generating component which needs to be cooled is attached and a second surface which is opposite to the first surface, and a plurality of fins protrudingly provided from the second surface of the heat receiving member. The plurality of fins include a first fin protrudingly provided on a first region of the second surface of the heat receiving member by a first attachment structure, and a second fin protrudingly provided on a second region of the second surface of the heat receiving member by a second attachment structure different from the first attachment structure.

### BRIEF DESCRIPTION OF THE DRAWINGS

An object, features, and advantages of the present invention will be more clearly by the description of the following embodiment related to the attached drawings.

In the attached drawings:

FIG. 1A is a perspective view illustrating a configuration of a heatsink according to the embodiment of the present invention;

FIG. 1B is an arrow IB view of FIG. 1A;

FIG. 2A is a perspective view illustrating a modified example of FIG. 1A;

FIG. 2B is an arrow IIB view of FIG. 2A;

FIG. 3A is a perspective view illustrating another modified example of FIG. 1A;

FIG. 3B is an arrow IIIB view of FIG. 3A;

FIG. 4A is a perspective view illustrating a further modified example of FIG. 1A; and

FIG. 4B is an arrow IVB view of FIG. 4A.

### DETAILED DESCRIPTION

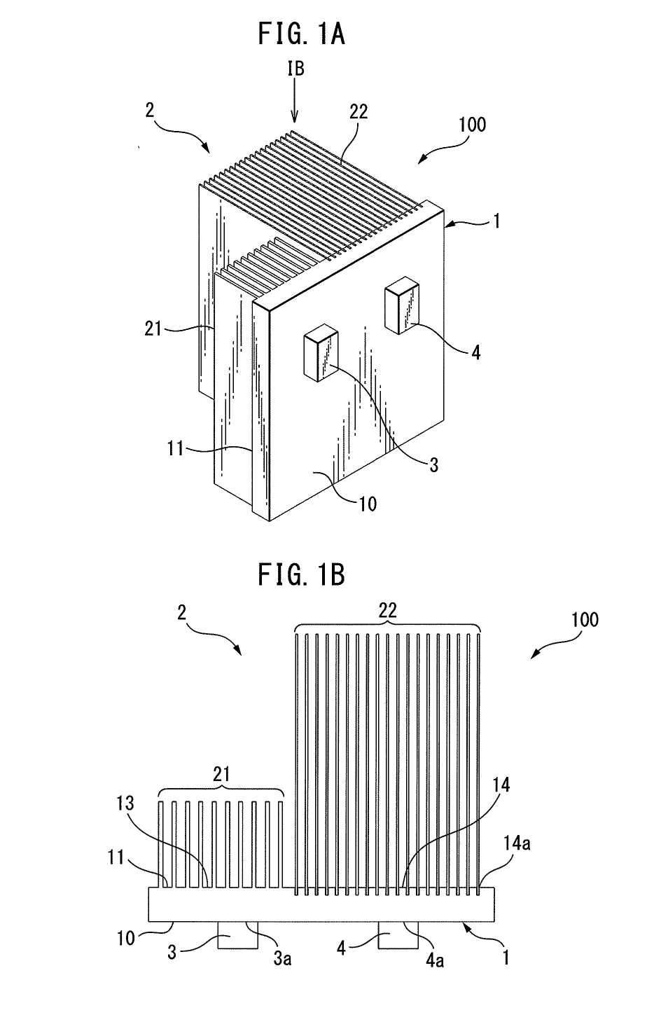

Hereinafter, an embodiment of the present invention will be described with reference to FIG. 1A to FIG. 4B. FIG. 1A is a perspective view illustrating a schematic configuration of a heatsink 100 according to the embodiment of the present invention, and FIG. 1B is an arrow IB view of FIG. 1A. As illustrated in FIG. 1A and FIG. 1B, the heatsink 100 comprises a heat receiving member 1 and plural fins 2 protrudingly provided from the heat receiving member 1.

The heat receiving member 1 is a substantially rectangular plate member having a first surface 10 and a second surface 11 which is opposite to the first surface, and plural (two in the drawings) heat generating components (a first heat generating component 3, a second heat generating component 4) are attached to the first surface 10 to be separated from each other. In other words, the first heat generating component 3 is attached to a first attachment part 3a and the second heat generating component 4 is attached to a second attachment part 4a respectively, on the first surface 10 through attachment means such as a bolt, an adhesive agent, and the like. An intervening object is interposed between the heat receiving member 1 and the heat generating components 3, 4, and the heat generating components 3, 4 can be attached through the intervening object.

The heat generating components 3, 4 can use a variety of components which need to be cooled, such as an electric component, an electronic component, and the like. It is preferable that the heat receiving member 1 and the fins 2 are metal having high thermal conductivity, such as aluminum, an aluminum alloy, copper, and a copper alloy, for example. Heat from the heat generating components 3, 4 is outwardly radiated through the heat receiving member 1 and the fins 2, and thus, the heat generating components 3, 4 can be cooled.

The fins 2 are formed to have a plate shape. As a characteristic configuration of the present embodiment, the plural fins 2 include plural first fins 21 and plural second fins 22 whose attachment structures are different from each other. The plural first fins 21 are attached at regular intervals to a first region 13 of the second surface 11 of the heat receiving member 1 by a first attachment structure. The plural second fins 22 are attached at regular intervals to a second region 14 of the second surface 11 of the heat receiving member 1, which is adjacent to the first region 13, by a second attachment structure different from the first attachment structure. Each of the first fins 21 and the second fins 22 extends in a direction perpendicular to the second surface 11 of the heat receiving member 1. The largest area surface of the first fins 21 in which the area is the largest and the largest area surface of the second fins 22 in which the area is the largest are parallel to each other. In other words, the first fins 21 and the second fins 22 extend in a direction parallel to each other. The distance (pitch) of the second fins 22 is narrower than the distance of the first fins 21, and the length from the attachment part of the fin to the tip portion of the fin (fin length) of the second fins 22 is longer than the first fins 21.

The first fins 21 are attached to the heat receiving member 1 by being integrally formed with the heat receiving member 1 by extrusion molding. In other words, the first attachment structure is extrusion molding.

Hereinafter, the fins attached by extrusion molding in this manner will be referred to as extrusion fins. The extrusion fins are suitable for use as fins for natural air cooling, which require a large volume, for example. The extrusion fins can be configured at a low cost because of an easy manufacturing method. On the other hand, the plate thickness of the fins is easy to be thickened, and when the size becomes big, a material cost increases. In addition, there are many limitations of the pitch, the fin length, the thickness, and the like of the extrusion fins, and it is difficult to form fins having a narrow pitch and a long length. In the present embodiment, the first fins 21 are the extrusion fins, and thus, the first fins 21 are configured to have a relatively wide pitch and a short length.

In contrast, the second fins 22 are formed separately from the heat receiving member 1 and are attached to the second surface 11 of the heat receiving member 1 by swaging. More specifically, concave portions 14a are formed on the second surface 11 of the heat receiving member 1, and the end portions of the second fins 22 are inserted into the concave portions 14a. Then, the concave portions 14a are swaged so that the second fins 22 are attached. In other words, the second attachment structure is swaging, and hereinafter, the fins attached by swaging in this manner will be referred to as swaging fins. Since the swaging fins can be configured to be thin, material cost is saved, and even large fins can be configured at a low cost. In addition, compared with the extrusion fins, the swaging fins have fewer limitations of the pitch, the fin length, the thickness, and the like of the fins. The foregoing swaging fins are suitable for being used for fins for forced air cooling, which require large surface area, for example. In the present embodiment, the second fins 22 are the swaging fins, and thus, the second fins 22 are configured to have a relatively narrow pitch and a long length.

As described above, in the present embodiment, the first fins 21 (extrusion fins) are protrudingly provided on the first region 13 of the second surface 11 of the heat receiving member 1 by the first attachment structure (extrusion molding), and the second fins 22 (swaging fins) are protrudingly provided on the second region 14 of the second surface 11 of the heat receiving member 1 by the second attachment structure (swaging). Therefore, the heatsink 100 provides radiation performance different from each other in the first region 13 and the second region 14, and can provide optimum radiation performance based on the calorific values, the sizes, and the arrangements of the heat generating components 3, 4.

For example, when the calorific value of the second heat generating component 4 is larger than the calorific value of the first heat generating component 3, as illustrated in FIG. 1A and FIG. 1B, the extrusion fins are provided as the first fins 21 on the first region 13 on the reverse side of the first heat generating component 3, and the swaging fins are provided as the second fins 22 on the second region 14 on the reverse side of the second heat generating component 4. The extrusion fins have radiation performance lower than the swaging fins, but can be configured at a low cost. Accordingly, necessary and sufficient cooling performance can be obtained while saving a manufacturing cost.

On the other hand, if both the first fins 21 and the second fins 22 are configured by the extrusion fins, sufficient cooling performance for the second heat generating component 4 may not be obtained. In addition, when both the first fins 21 and the second fins 22 are configured by the swaging fins, manufacturing cost increases, and furthermore, cooling performance for the first fins 21 becomes excessive. In order to resolve the excessive cooling performance, a heatsink for a first heat generating component and a heatsink for a second heat generating component need to be separately formed. As a result, the configuration of the heatsinks becomes complicated, and manufacturing cost also increases.

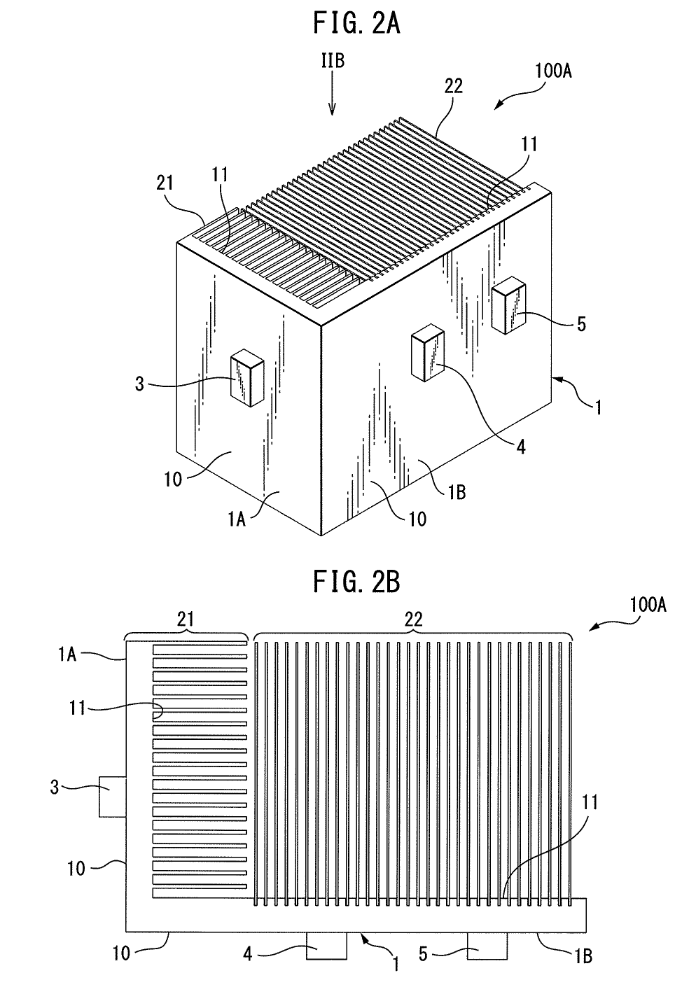

Modified examples of the present invention will be described with reference to FIG. 2A to FIG. 4B. FIG. 2A is a perspective view of a heatsink 100A which is a first modified example of the present invention, and FIG. 2B is an arrow IIB view of FIG. 2A. In the heatsink 100A of the first modified example, the heat receiving member 1 has a first flat plate part 1A and a second flat plate part 1B which are perpendicular to each other, and the heat receiving member 1 has a substantially L shape, as illustrated in FIG. 2B. The first heat generating component 3 is attached to the first surface 10 of the first flat plate part 1A, and the second heat generating component 4 and a third heat generating component 5 are attached to the first surface 10 of the second flat plate part 1B.

The plural first fins 21 (extrusion fins) are provided at regular intervals on the second surface 11 of the first flat plate part 1A (first region) so as to extend in a direction perpendicular to the second surface 11. The plural second fins 22 (swaging fins) are provided at regular intervals on the second surface 11 of the second flat plate part 1B (second region) so as to extend in a direction perpendicular to the second surface 11. In other words, in the first modified example, the second surface 11 of the first flat plate part 1A and the second surface 11 of the second flat plate part 1B are perpendicular. The second surface 11 of the first flat plate part 1A corresponds to a first flat surface. The second surface 11 of the second flat plate part 1B corresponds to a second flat surface. The first fins 21 and the second fins 22 extend in directions perpendicular to each other. In other words, an extending direction of the largest area surface of the first fins 21 and an extending direction of the largest area surface of the second fins 22 are perpendicular to each other. The tip portions of the first fins 21 are close to a side surface of the second fins 22. The tip portions of the second fins 22 are located on an extension of the end surface of the first flat plate part 1A parallel to the second surface 11 of the second flat plate part 1B.

Accordingly, the plural fins 21, 22 can be efficiently arranged on the second surface 11 of the heatsink 100A whose maximum dimension is defined by the first flat plate part 1A and the second flat plate part 1B, and the heatsink 100A which is compact and has high radiation performance can be configured. In addition, in the first modified example, the single heat generating component 3 is arranged on the first surface 10 of the first flat plate part 1A on the reverse side of the attachment parts of the first fins 21 (first attachment part), and the plural heat generating components 4, 5 are arranged on the first surface 10 of the second flat plate part 1B on the reverse side of the attachment parts of the second fins 22 (second attachment part). Thus, more heat is transferred from the heat generating components 3 to 5 to the second flat plate part 1B than the first flat plate part 1A, but since the extrusion fins are used for the first fins 21 and the swaging fins having higher radiation performance than the extrusion fins are used for the second fins 22, the plural heat generating components 3 to 5 can be necessarily and sufficiently cooled.

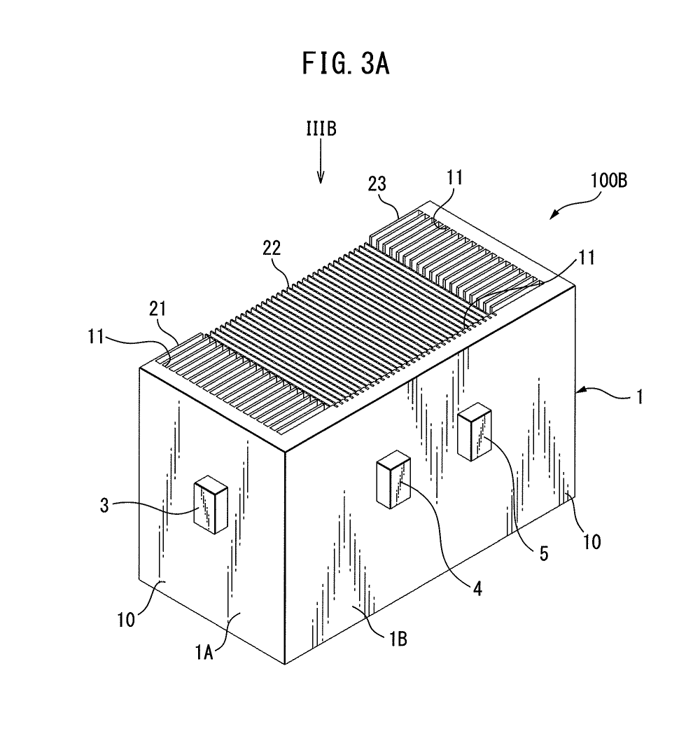

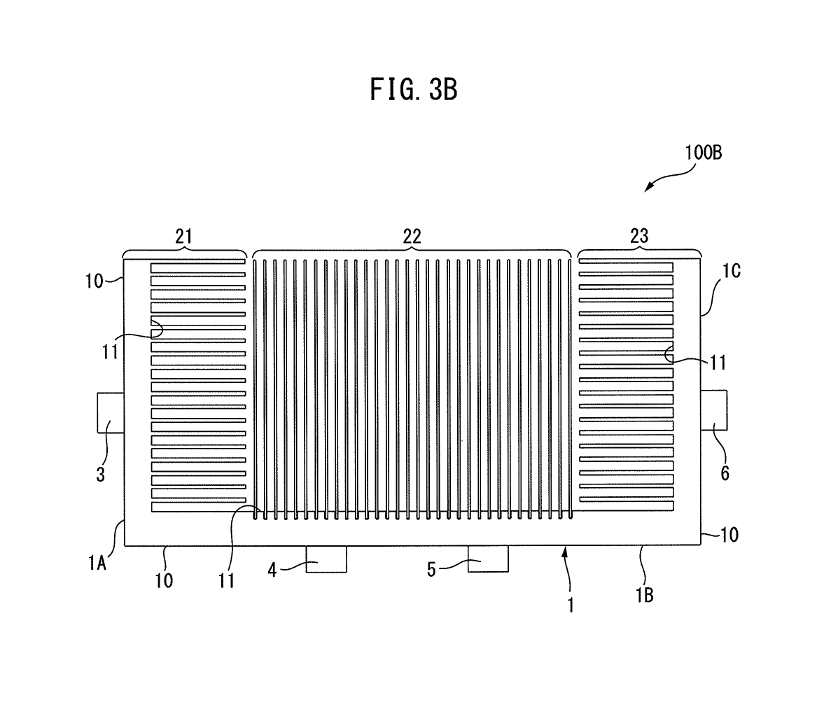

FIG. 3A is a perspective view of a heatsink 100B which is a second modified example of the present invention, and FIG. 3B is an arrow IIIB view of FIG. 3A. In the heatsink 100B of the second modified example, the heat receiving member 1 has the first flat plate part 1A, the second flat plate part 1B, and a third flat plate part 1C. Extending directions of the first flat plate part 1A and the second flat plate part 1B are perpendicular to each other. Extending directions of the second flat plate part 1B and the third flat plate part 1C are perpendicular to each other. As illustrated in FIG. 3B, the heat receiving member 1 has a planar shape of a substantially U shape. The first heat generating component 3 is attached to the first surface 10 of the first flat plate part 1A, the second heat generating component 4 and the third heat generating component 5 are attached to the first surface 10 of the second flat plate part 1B, and a fourth heat generating component 6 is attached to the first surface 10 of the third flat plate part 1C.

The plural first fins 21 (extrusion fins) are provided at regular intervals on the second surface 11 of the first flat plate part 1A (first region) so as to extend in a direction perpendicular to the second surface 11. The plural second fins 22 (swaging fins) are provided at regular intervals on the second surface 11 of the second flat plate part 1B so as to extend in a direction perpendicular to the second surface 11. Plural third fins 23 (extrusion fins) are provided at regular intervals on the second surface 11 of the third flat plate part 10 (third region) so as to extend perpendicularly to the second surface 11. In other words, in the second modified example, the first fins 21 and the third fins 23 extend parallel to each other, and the second fins 22 extend in a direction perpendicular to the first fins 21 and the third fins 23.

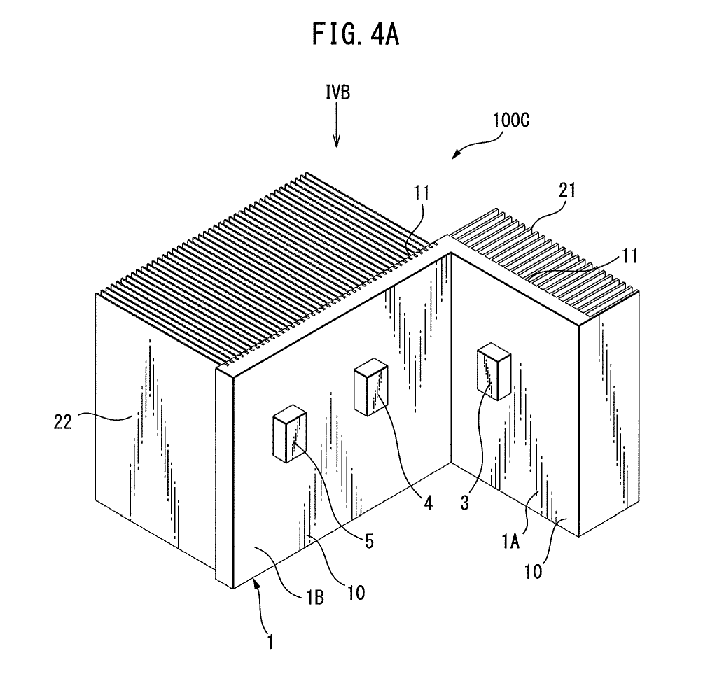

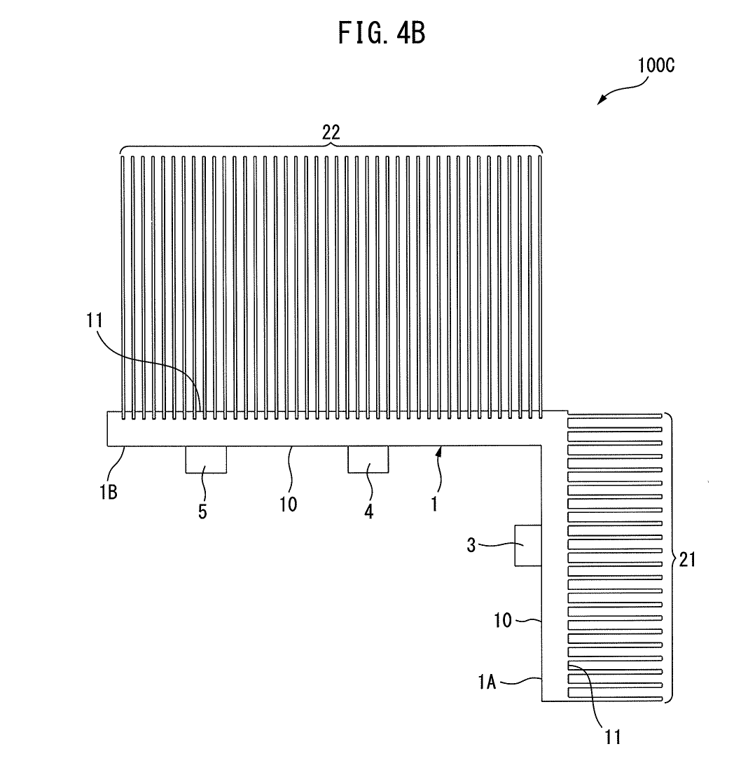

FIG. 4A is a perspective view of a heatsink 100C which is a third modified example of the present invention, and FIG. 4B is an arrow IVB view of FIG. 4A. In the heatsink 100C of the third modified example, the heat receiving member 1 has the first flat plate part 1A and the second flat plate part 1B which are perpendicular to each other. In the heatsink 100A (FIG. 2B) of the first modified example, the angle between the second surface 11 of the first flat plate part 1A and the second surface 11 of the second flat plate part 1B is 90°, and in contrast, in the third modified example, the angle between the first surface 10 of the first flat plate part 1A and the first surface 10 of the second flat plate part 1B is 90°. Therefore, the first fins 21 (extrusion fins) protrudingly provided from the second surface 11 of the first flat plate part 1A extend in a direction away from the second fins 22 (swaging fins) protrudingly provided from the second surface 11 of the second flat plate part 1B.

In the embodiment and the modified examples described above, the extrusion fins are used as the first fins 21 and the swaging fins are used as the second fins 22, but other fins whose attachment structures are different from each other (for example, brazing fins, soldering fins, adhering fins, and the like) can also be used.

The brazing fins can be obtained by connecting the end portions of the fins to the second surface 11 of the heat receiving member 1 by brazing. When manufacturing the brazing fins, a high-temperature furnace becomes necessary, and a manufacturing cost increases. On the other hand, the brazing fins have few limitations of the pitch, the fin length, the thickness, and the like. In addition, a swaging region as in the swaging fins is unnecessary, and fins having a narrower pitch and a longer length than the swaging fins can be formed. The foregoing brazing fins are suitable for being used for fins for forced air cooling, which require a large surface area.

The soldering fins can be obtained by connecting the end portions of the fins with the second surface 11 of the heat receiving member 1 by soldering. The adhering fins can be obtained by bonding the end portions of the fins to the second surface 11 of the heat receiving member 1 using an adhesive agent having thermal conductivity, for example. The adhering fins can be configured at a lower cost compared with the brazing fins and the soldering fins, but have poorer radiation performance compared with the brazing fins and the soldering fins because contact thermal resistance between the heat receiving member 1 and the fins is large.

The configurations of the first fins and the second fins are not limited to those described above, as long as the first fins 21 and the second fins 22 are configured using two of extrusion molding, swaging, brazing, soldering, and adhering as the attachment structures of the fins 2 (first attachment structure, second attachment structure). Any one or both of the first fins and the second fins may be protrudingly provided from the second surface 11 not in a perpendicular direction but in an oblique direction. In the modified example described above (FIG. 3B), the third fins 23 have the same configuration as the first fins 21, but may have a configuration different from the first fins 21 and the second fins 22. In other words, three types or more of fins whose attachment structures are different from each other may be protrudingly provided from regions of the heat receiving member 1, which are different from each other.

In the embodiment described above, the first heat generating component 3 is attached to the first attachment part 3a on the opposite side of the first region 13 of the heat receiving member 1 and the second heat generating component 4 is attached to the second attachment part 4a on the opposite side of the second region 14 of the heat receiving member 1, but the first attachment part and the second attachment part may be provided at positions other than those described above, as long as the first attachment part 3a and the second attachment part 4a are arranged at positions corresponding to the first region 13 and the second region 14, respectively. In the embodiment described above, the plural heat generating components 3, 4 are arranged on the heat receiving member 1, but the present invention is effective also when a single heat generating component with temperature distribution is arranged on the heat receiving member 1, for example.

In the modified example described above (FIG. 2B), the first flat plate part 1A and the second flat plate part 1B are formed so that the largest area surfaces in which the areas are the largest are perpendicular. The heatsink is formed so that the first fins 21 are protrudingly provided from the second surface 11 of the first flat plate part 1A (first flat surface) and the second fins 22 are protrudingly provided from the second surface 11 of the second flat plate part 1B (second flat surface), but the first flat surface and the second flat surface may be obliquely crossed without being perpendicular. In other words, the configuration of the heat receiving member 1 is not limited to that described above, and for example, the heat receiving member 1 may be configured to have a case shape and the first fins 21 and the second fins 22 may be arranged in a closed space inside thereof. In addition, the length and the shape of each of the fins, and the pitch between the fins may be different.

The heatsink according to the present invention has the first fins protrudingly provided on the first region of the second surface of the heat receiving member by the first attachment structure, and the second fins protrudingly provided on the second region of the second surface of the heat receiving member by the second attachment structure different from the first attachment structure. Therefore, the heatsink provides radiation performance different from each other in the first region and the second region, and can provide optimum radiation performance based on the calorific values of the heat generating components.

The above description is merely an example, and the present invention is not limited to the embodiment and the modified examples described above without impairing the features of the present invention. The components of the embodiment and the modified examples described above include ones that can be substituted and are obviously substituted while maintaining consistency of the invention. In other words, other modes considered within the range of the technical idea of the present invention are also included in the range of the present invention. In addition, the embodiment and one or plural of the modified examples described above can be arbitrarily combined.

1. A heatsink comprising:
a heat receiving member having a first surface to which a heat generating component which needs to be cooled is attached and a second surface which is opposite to the first surface; and
a plurality of fins protrudingly provided from the second surface of the heat receiving member, wherein
the plurality of fins include a first fin protrudingly provided on a first region of the second surface of the heat receiving member by a first attachment structure, and a second fin protrudingly provided on a second region of the second surface of the heat receiving member by a second attachment structure different from the first attachment structure.

2. The heatsink according to claim 1, wherein
the heat receiving member has a first attachment part provided on the opposite side of the first region and to which a first heat generating component is attached, and a second attachment part provided on the opposite side of the second region and to which a second heat generating component is attached.

3. The heatsink according to claim 1, wherein
the second surface of the heat receiving member includes a first flat surface and a second flat surface which are crossed with each other, the first fin is protrudingly provided from the first flat surface, and the second fin is protrudingly provided from the second flat surface.

4. The heatsink according to claim 3, wherein
the first flat surface is perpendicular to the second flat surface.

5. The heatsink according to claim 1, wherein
the first attachment structure and the second attachment structure are any two of extrusion molding, swaging, brazing, soldering, and adhering.
